(19) United States
(12) Patent Application Publication
(10) Pub. No.: US 2012/0121856 A1
(43) Pub. Date: May 17, 2012

(54) COATED ARTICLE AND METHOD FOR MAKING SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); ZHI-JIE HU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/188,060

(22) Filed: Jul. 21, 2011

(30) Foreign Application Priority Data
Nov. 11, 2010 (CN) 201010539905.8

(51) Int. Cl. B32B 3/00; C23C 14/34; C23C 14/08

(52) U.S. Cl. 428/141; 204/192.1; 204/192.15

(57) ABSTRACT

A coated article is provided. The coated article includes a substrate, a bonding layer formed on the substrate, and an anti-fingerprint layer formed on the bonding layer. The bonding layer comprises silicon-oxygen compound and has a plurality of nano-sized mastoids on a surface boding the anti-fingerprint layer. The anti-fingerprint layer comprises polytetrafluoroethylene and has a profile corresponding to the profile of the bonding layer. A method for making the coated article is also described there.

### BACKGROUND

1. Technical Field

The present disclosure relates to coated articles, particularly to a coated article having an anti-fingerprint property and a method for making the coated article.

2. Description of Related Art

Many electronic housings are coated with an anti-fingerprint layer. These anti-fingerprint layers are commonly painted on with a paint containing organic anti-fingerprint substances. However, the anti-fingerprint layers that are painted on usually have low bonding force with metal substrates and therefore may not last very long. Furthermore, the paint may not be environmentally friendly.

Therefore, there is room for improvement within the art.

### BRIEF DESCRIPTION OF THE FIGURES

Many aspects of the coated article can be better understood with reference to the following figures. The components in the figure are not necessarily drawn to scale, the emphasis instead being placed upon clearly illustrating the principles of the coated article.

FIG. 1 is a cross-sectional view of an exemplary embodiment of a coated article.

FIG. 2 is a cross-sectional view of another exemplary embodiment of a coated article.

### DETAILED DESCRIPTION

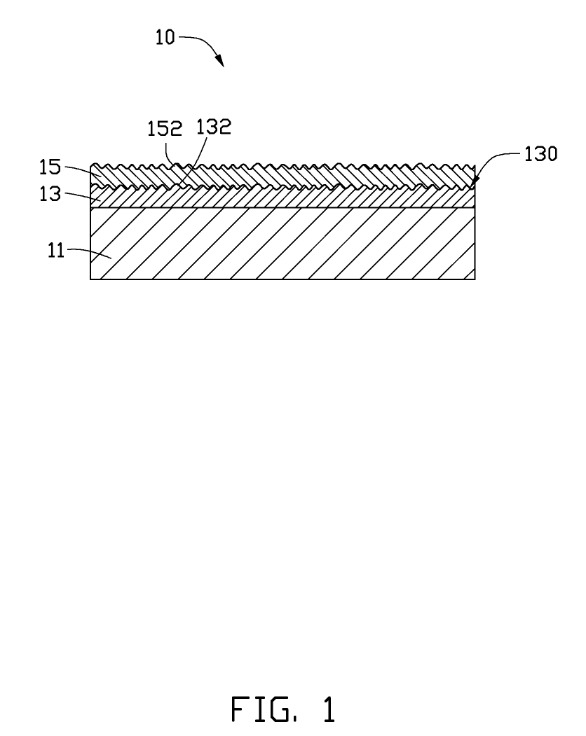

FIG. 1 shows a coated article 10 according to an exemplary embodiment. The coated article 10 includes a substrate 11, a bonding layer 13 formed on a surface of the substrate 11, and an anti-fingerprint layer 15 formed on the bonding layer 13.

The substrate 11 may be made of metal or non-metal material. The metal may be selected from the group consisting of stainless steel, aluminum, aluminum alloy, magnesium, magnesium alloy, copper, copper alloy, and zinc. The non-metal material may be plastic, ceramic, or glass.

The bonding layer 13 is a silicon-oxygen compound coating formed by vacuum sputtering, such as RF magnetron sputtering. The silicon-oxygen compound may be SiₓO_{y}, in which the “x” and “y” satisfy the following relationship: y≧2x. That is, in the bonding layer 13, the silicon-oxygen compound is oxygen saturated or supersaturated. The bonding layer 13 has a plurality of nano-sized mastoids 132 on its surface 130 bonding with the anti-fingerprint layer 15. The bonding layer 13 may be transparent and may have a thickness of about 100 nm-600 nm.

The anti-fingerprint layer 15 may be a polytetrafluoroethylene (PTFE) layer formed by vacuum sputtering, such as RF magnetron sputtering. The anti-fingerprint layer 15 is directly formed on the surface 130 of the bonding layer 13 and has a profile corresponding to the profile of the bonding layer 13. Thereby, the anti-fingerprint layer 15 has a plurality of nano-sized mastoids 152 formed thereon. The anti-fingerprint layer 15 may be about 10 nm-150 nm thick, so it does not fill up the nano-sized mastoids 132 to create a flat surface. The anti-fingerprint layer 15 may be transparent.

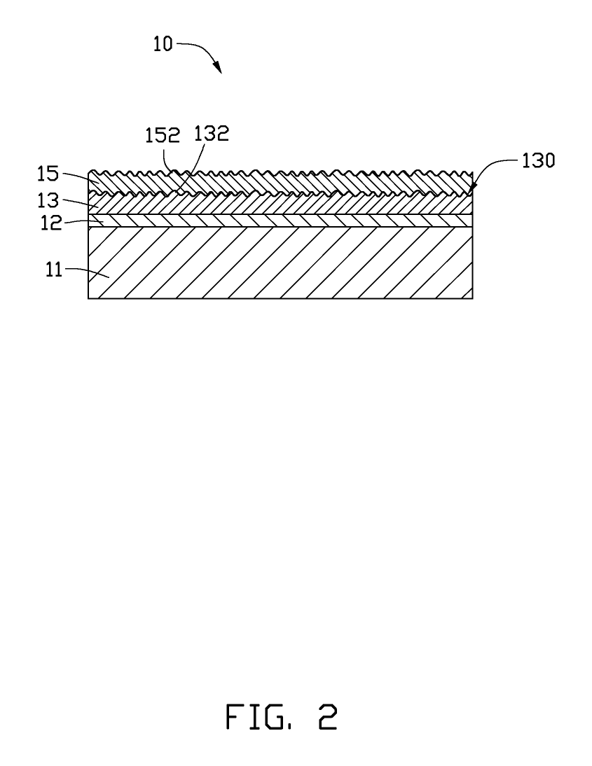

Referring to FIG. 2, in a second embodiment, the coated article 10 may further include a decorative layer 12 located between the substrate 11 and the bonding layer 13, to provide decorative color for the coated article 10. The decorative layer 12 may be a metallic coating formed by vacuum sputtering.

The anti-fingerprint layer 15 comprising PTFE has a very low surface energy, reducing the surface energy of the coated article 10. The bonding layer 13 comprising silicon-oxygen compound has silicon dangling bonds. The anti-fingerprint layer 15 comprising PTFE has C-F bonds. The C-F bonds combine with the silicon dangling bonds, thereby enhancing the attachment of the anti-fingerprint layer 15 to the substrate 11. Furthermore, the anti-fingerprint layer 15 having a profile corresponding to the profile of the bonding layer 13 has a plurality of nano-sized mastoids 152 formed thereon. The nano-sized mastoids 152 can alter the contact angle between a given fluid and the coated article 10. This effect is also known as the “lotus leaf” effect. Accordingly, the coated article 10 is both hydrophobic and oleophobic, achieving a good anti-fingerprint property.

An exemplary method for making the coated article 10 may include the following steps:

The substrate 11 is provided.

The substrate 11 is pretreated. For example, the substrate 11 is ultrasonically cleaned with a solution (e.g., alcohol or acetone) in an ultrasonic cleaner, to remove impurities such as grease or dirt from the substrate 11. Then, the substrate 11 is dried.

The transition layer 13 is vacuum sputtered on the pretreated substrate 11. In this exemplary embodiment, the vacuum sputtering is RF magnetron sputtering. Vacuum sputtering of the transition layer 13 is implemented in a vacuum chamber of a vacuum sputtering machine (not shown). The substrate 11 is positioned in the vacuum chamber. The vacuum chamber is fixed with silicon dioxide (SiO₂) targets and PTFE targets therein. The inside of the vacuum chamber is heated to maintain a temperature of about 20° C.-300° C. Argon (Ar) and oxygen (O₂) are simultaneously fed into the chamber, with the Ar as a sputtering gas, and the oxygen as a reactive gas. The flow rate of the Ar may be about 100 standard-state cubic centimeters per minute (sccm) to 200 sccm. The flow rate of the O₂ is about 30 sccm-100 sccm. A bias voltage of about −200 V to about −350 V may be applied to the substrate 11. About 100 W-250 W of electric power is applied to the SiO₂ targets fixed in the chamber, depositing the bonding layer 13 on the substrate 11. The deposition of the bonding layer 13 may take about 10 min-60 min. The O₂ is used to compensate for the oxygen atoms lost during the deposition in this step. The electric power is a radio-frequency power in this exemplary embodiment. The bonding layer 13 deposited under the above conditions has the nano-sized mastoids 132 formed on its surface 130.

Then, the bonding layer 13 is plasma bombarded to etch the surface 130. The nano-sized mastoids 132 are enlarged by the etching of the plasma. The plasma bombarding step is implemented in the vacuum chamber of the vacuum sputtering machine. The SiO₂ targets are switched off and the feeding of the O₂ is stopped. The bias voltage applied on the substrate 11 is maintained at about −200 V to about −350 V. The temperature inside the vacuum chamber is maintained at about 20° C.-300° C. The flow rate of the Ar is adjusted to about 250 sccm-400 sccm. The Ar is ionized to plasma. The plasma then bombards and etches the surface 130 of the bonding layer 13 to enlarge the nano-sized mastoids 132. Additionally, the bombardment of the plasma increases the number of the silicon dangling bonds on the surface 130 of the bonding layer 13, facilitating the bonding of the subsequently formed anti-fingerprint layer 15. Plasma bombarding of the bonding layer 13 may take about 10 min-30 min.

The anti-fingerprint layer 15 is directly formed on the bonding layer 13 by RF magnetron sputtering. Sputtering of the anti-fingerprint layer 15 is implemented in the vacuum chamber of the vacuum sputtering machine. The internal temperature of the vacuum chamber is maintained at about 20° C.-300° C. Argon (Ar) may be used as a sputtering gas and is fed into the chamber at a flow rate of about 100 sccm-200 sccm. A bias voltage of about −50 V to about −150 V may be applied to the substrate 11. About 50 W-200 W of electric power is applied to the PTFE targets fixed in the chamber, depositing the anti-fingerprint layer 15 on the bonding layer 13. The deposition of the anti-fingerprint layer 15 may take about 5 min-15 min. The electric power is a radio-frequency power in this exemplary embodiment.

The anti-fingerprint property of the anti-fingerprint layer 15 has been tested by using a dyne test pen (brand: ACCU; the place of production: U.S.A.). The test has indicated that the surface tension of the anti-fingerprint layer 15 is below 30 dynes, thus, the anti-fingerprint layer 15 has a good anti-fingerprint property.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A coated article, comprising:
a substrate;
a bonding layer formed on the substrate, the bonding layer comprising silicon-oxygen compound, and the bonding layer having a plurality of nano-sized mastoids on a surface thereof; and
an anti-fingerprint layer formed on the bonding layer, the anti-fingerprint layer comprising polytetrafluoroethylene and having a profile corresponding to the profile of the bonding layer.

2. The coated article as claimed in claim 1, wherein silicon-oxygen compound is SiₓO_{y}, in which the “x” and “y” satisfy the following relationship: y≧2x.

3. The coated article as claimed in claim 1, wherein the anti-fingerprint layer has a plurality of nano-sized mastoids formed thereon.

4. The coated article as claimed in claim 1, wherein the bonding layer has a thickness of about 100 nm-600 nm; the anti-fingerprint layer has a thickness of about 10 nm-150 nm.

5. The coated article as claimed in claim 1, wherein the bonding layer and the anti-fingerprint layer both are formed by vacuum sputtering.

6. The coated article as claimed in claim 1, wherein the bonding layer and the anti-fingerprint layer both are transparent.

7. The coated article as claimed in claim 1, further comprising a metallic decorative layer formed between the substrate and the bonding layer.

8. The coated article as claimed in claim 1, wherein the substrate is made of metal or non-metal material.

9. The coated article as claimed in claim 8, wherein the metal is selected from the group consisting of stainless steel, aluminum, aluminum alloy, magnesium, magnesium alloy, copper, copper alloy, and zinc.

10. The coated article as claimed in claim 8, wherein the non-metal material is selected from the group consisting of plastic, ceramic, and glass.

11. A method for making a coated article, comprising:
providing a substrate;
forming a bonding layer comprising silicon-oxygen compound on the substrate by vacuum sputtering, the bonding layer having a plurality of nano-sized mastoids formed on a surface thereof; and
forming an anti-fingerprint layer comprising polytetrafluoroethylene on the bonding layer by vacuum sputtering, the anti-fingerprint layer having a profile corresponding to the profile of the bonding layer.

12. The method as claimed in claim 11, wherein vacuum sputtering the bonding layer uses silicon oxide targets applied with a radio-frequency power of about 100 W to about 250 W; uses oxygen at a flow rate of about 30 sccm to about 100 sccm as a reaction gas;
uses argon at a flow rate of about 100 sccm to about 200 sccm as a sputtering gas; applies a bias voltage of about −200 V to about −350 V to the substrate; and is carried out under a temperature of about 20° C. to about 300° C.

13. The method as claimed in claim 11, wherein vacuum sputtering the anti-fingerprint layer uses polytetrafluoroethylene targets applied with a radio-frequency power of about 50 W to about 200 W; uses argon at a flow rate of about 100 sccm to about 200 sccm as a sputtering gas; applies a bias voltage of about −50 V to about −150 V to the substrate;
vacuum sputtering the anti-fingerprint layer is at a temperature of about 20° C.-300° C.

14. The method as claimed in claim 11, further comprising a step of plasma bombarding the bonding layer to enlarge the nano-sized mastoids, before the step of forming the anti-fingerprint layer.

15. The method as claimed in claim 14, wherein the plasma bombarding uses argon at a flow rate of about 250 sccm to about 400 sccm for generating plasma; applies a bias voltage of about −200 V to about −350 V to the substrate; the plasma bombarding is carried out under a temperature of about 20° C.-300° C.

16. The method as claimed in claim 14, wherein the plasma bombarding takes about 10 min to about 30 min.

17. The method as claimed in claim 11, further comprising a step of ultrasonically cleaning the substrate before forming the bonding layer.

18. The method as claimed in claim 11, wherein the substrate is made of metal material or non-metal material.

19. The method as claimed in claim 18, wherein the metal is selected from a group consisting of stainless steel, aluminum, aluminum alloy, magnesium, magnesium alloy, copper, copper alloy, and zinc.

20. The method as claimed in claim 18, wherein the non-metal material is selected from the group consisting of plastic, ceramic, and glass.
